(19) United States
(12) Patent Application Publication
(10) Pub. No.: US 2024/0306482 A1
(43) Pub. Date: Sep. 12, 2024

(54) VACUUM DRYING APPARATUSES, VACUUM DRYING METHODS AND DISPLAY PANELS

(71) Applicant: Shenzhen China Star Optoelectronics Semiconductor Display Technology Co., Ltd., Shenzhen (CN)

(72) Inventor: Youyuan KUANG, Shenzhen (CN)

(73) Assignee: Shenzhen China Star Optoelectronics Semiconductor Display Technology Co., Ltd., Shenzhen (CN)

(21) Appl. No.: 18/533,342

(22) Filed: Dec. 8, 2023

(30) Foreign Application Priority Data
Mar. 6, 2023 (CN) 202310239680.1

(51) Int. Cl. H10K 71/40; F26B 5/04

(52) U.S. Cl. CPC H10K 71/441; F26B 5/04

(57) ABSTRACT

The present disclosure provides a vacuum drying apparatus, a vacuum drying method, and a display panel; the vacuum drying apparatus includes a cavity, and an abutment and a condenser disposed within the cavity; the abutment includes a first side configured to carry a substrate and having a first temperature; the condenser includes a second side facing the first side and having a second lower than temperature lower than the first temperature; the second side includes a first part configured to face a center area of the substrate and a second part surrounding the first part, and a temperature of the first part is lower than a temperature of the second part.

### CROSS-REFERENCE TO RELATED APPLICATION

The present disclosure claims the priority to and benefit of Chinese Patent Application 202310239680.1, filed on Mar. 6, 2023, the disclosure of which is incorporated herein by reference in its entirety.

### TECHNICAL FIELD

The present disclosure relates to the field of display, and in particular, to the manufacturing of display devices. Specifically, the present disclosure relates to vacuum drying apparatuses, vacuum drying methods and display panels.

### BACKGROUND

Organic light-emitting diode (OLED) display panels use self-luminous technology for screen display, and have advantages such as a fast response speed, high contrast, a wide viewing angle, and the like.

At present, especially for large-size OLED display panels, the emerging mass production method is printing, that is inkjet printing, in which a vacuum dry (VCD) process is required to remove solvents from ink and leave solutes in the ink to form OLED functional layers. During the VCD process, the gas generated in edge areas of the OLED display panels is removed earlier than the gas generated in center areas of the OLED display panels, which makes the ink in the edge areas dry faster, resulting in the display difference between sub-pixels in the edge areas and sub-pixels in the center areas of the OLED display panels, which causes uneven display of the image.

Based on the above, the existing OLED display panels have uneven display due to different drying rates of the ink in the edge and center areas during the VCD process, which urgently needs to be improved.

### SUMMARY

Embodiments of the present disclosure provide a vacuum drying apparatus, including:
a cavity;
an abutment disposed within the cavity and including a first side configured to carry a substrate having a first temperature; and
a condenser disposed within the cavity and including a second side facing the first side having a second temperature lower than the first temperature;
in which the second side includes a first part configured to face a center area of the substrate and a second part surrounding the first part, and a temperature of the first part is lower than a temperature of the second part.

Embodiments of the present disclosure provide a vacuum drying method for the vacuum drying apparatus, including:
providing the vacuum drying apparatus and a substrate, in which the vacuum drying apparatus includes a cavity, and an abutment and a condenser disposed within the cavity; the abutment includes a first side configured to carry the substrate and having a first temperature; the condenser includes a second side facing the first side, and the second side includes a first part configured to face a center area of the substrate and a second part surrounding the first part;
placing the center area of the substrate on a center area of the first side of the abutment;
controlling a medium to flow into an inlet of the condenser and flow out of an outlet of the condenser, so that the second side has a second temperature lower than the first temperature, and a temperature of the first part is lower than a temperature of the second part.

Embodiments of the present disclosure further provide a display panel, prepared using the vacuum drying apparatus as described above.

### BRIEF DESCRIPTION OF THE DRAWINGS

The present disclosure will be further described below with reference to the attached drawings. It should be noted that the attached drawings in the following description are only used to explain some embodiments of the present disclosure. For those skilled in the art, other drawings can also be obtained based on these drawings without any creative effort.

FIG. 1 is a schematic cross-sectional diagram of a vacuum drying apparatus provided by some embodiments of the present disclosure.

FIG. 2 is a schematic top view diagram of a condenser in a vacuum drying apparatus provided by some embodiments of the present disclosure.

FIG. 3 is a flowchart of a vacuum drying method provided by some embodiments of the present disclosure.

### DETAILED DESCRIPTION

Technical solutions in the embodiments of the present disclosure will be described with reference to the attached drawings definitely and completely in the following. Apparently, the described embodiments are only a part of the embodiments of the present disclosure, not all of them. Based on the embodiments in the present disclosure, all other embodiments obtained by those skilled in the art without creative labor fall within the scope of protection of the present disclosure.

In the description of the present disclosure, it should be understood that, directional or positional relationships indicated by the terms “close to”, “away from”, and the like, are based on the directional or positional relationships shown in the attached drawings. For example, “on” only refers to a surface of a device or an element disposed above an object, specifically referring to “right above”, “oblique above”, or “upper surface”, as long as it is above the object in a horizontal direction. The above directional or positional relationships are only for the convenience of describing the present disclosure and simplifying the description, and does not indicate or imply that the device or element referred to must have a specific orientation, be constructed and operated in a specific orientation, and therefore cannot be understood as a limitation on the present disclosure.

In addition, terms “first”, “second”, and the like, are only used to describe the purpose and cannot be understood as indicating or implying relative importance or implying the quantity of technical features indicated. Therefore, the features defined by “first” and “second” can explicitly or implicitly include one or more of the features. In the description of the present disclosure, “multiple” means two or more, unless otherwise specified. In addition, it should also be noted that the attached drawings only provide structures and steps that are closely related to the present disclosure, and omit some details that are not related to the present disclosure. The purpose is to simplify the attached drawings and make the present disclosure point clear at a glance, rather than indicating that the devices and methods in practice are exactly the same as those in the attached drawings, which is not a limitation on the devices and methods in practice.

The present disclosure provides a vacuum drying apparatus, which include, but not limited to, any of vacuum drying apparatuses provided in the following embodiments or combinations thereof.

In some embodiments, as shown in FIG. 1, a vacuum drying apparatus 100 includes a cavity 10, an abutment 20, and a condenser 30. The abutment 20 is disposed within the cavity 10 and includes a first side D1 configured to carry a substrate 200, and the first side D1 has a first temperature. The condenser 30 is disposed within the cavity 10 and includes a second side D2 facing the first side D1, and the second side D2 has a second temperature lower than the first temperature. The second side D2 includes a first part D21 disposed opposite to a center area of the substrate 200 and a second part D22 surrounding the first part D21, and a temperature of the first part D21 is lower than that a temperature of the second part D22. It should be understood that the second temperature include two temperatures lower than the first temperature, and the two temperatures are the temperature of the first part D21 and the temperature of the second part D22, respectively.

The substrate 200 may be, but not limited to, a semi-finished OLED display panel, which may include a base, a circuit layer disposed on the base, and a pixel layer to be dried disposed on the circuit layer. The pixel layer to be dried may include a pixel definition layer provided with multiple openings, and each of the openings is filled with ink of the corresponding color. Ink of different colors may be respectively formed in the corresponding openings by inkjet printing, but not limited on this process. It should be noted that, since the ink is a liquid solution, a vacuum drying process is used to remove solvents from the ink, leaving solutes in the ink to form sub-pixels of corresponding colors.

Specifically, the cavity 10 may be equipped with a chamber door configured to allow the substrate 200 to be dried to enter or leave the cavity 10 when the cavity 10 is opened, and for closing the cavity 10 to form a relatively enclosed space after the substrate 200 to be dried enters the cavity 10, so as to perform the drying treatment on the substrate 200 to be dried. The abutment 20 is disposed opposite to the condenser 30. The first side D1 of the abutment 20 close to the condenser 30, which has the first temperature, and the second side D2 of the condenser 30 close to the abutment 20, which has the second temperature lower than the first temperature, resulting in a temperature difference between the first side D1 of the abutment 20 and the second side D2 of the condenser 30. The design of the first side D1 having the higher first temperature enables the solvents in the ink for preparing the pixel layer to evaporate into gas. By setting the second temperature of the second side D2 to be lower than the first temperature, it can accelerate the evaporation rate of the solvents from the ink.

In some embodiments, the vacuum drying apparatus 100 may also include a lifting column 40 for supporting the abutment 20 and controlling the movement of the abutment 20 in both of a vertical direction and a horizontal direction. Further, the cavity 10 may also include an extraction pump 50 disposed close to an edge of the abutment 20. During the process for heating the substrate 200 to be dried, the extraction pump 50 may extract the gas formed by evaporating the solvents from the ink to leave the cavity 10, so as to further increase the evaporation rate of the solvents from the ink.

In the embodiments as illustrated in FIG. 1, the second side D2 includes a first part D21 disposed facing the center area of the substrate 200 and a second part D22 surrounding the first part D21; and a temperature of the first part D21 is lower than a temperature of the second part D22. That is, the temperatures of the second side D2 at different positions are different. Specifically, the temperature of the first part D21 disposed facing the center area of the substrate 200 is lower. According to the above description, it can be understood that the first temperature of the abutment 20 is higher than the second temperature. For example, if the first temperature is 20° C., the second temperature may be 10° C. Therefore, the embodiments of the present disclosure can achieve the effect that a temperature difference between the first part D21 and the abutment 20 is higher than a temperature difference between the second part D22 and the abutment 20. That is, in terms of the temperature, the evaporation rate of the solvents from the ink at the center area of the substrate 200 is faster, which can compensate for the faster evaporation rate of the solvents from the ink close to the edge of the substrate 200 caused by the extraction pump 50, thereby reducing the difference between the evaporation rate of the solvents from the ink close to the edge area of the substrate 200 and the evaporation rate of the solvents from the ink close to the center area of the substrate 200, and reducing the risk of uneven display in the OLED display panel formed in the later stage.

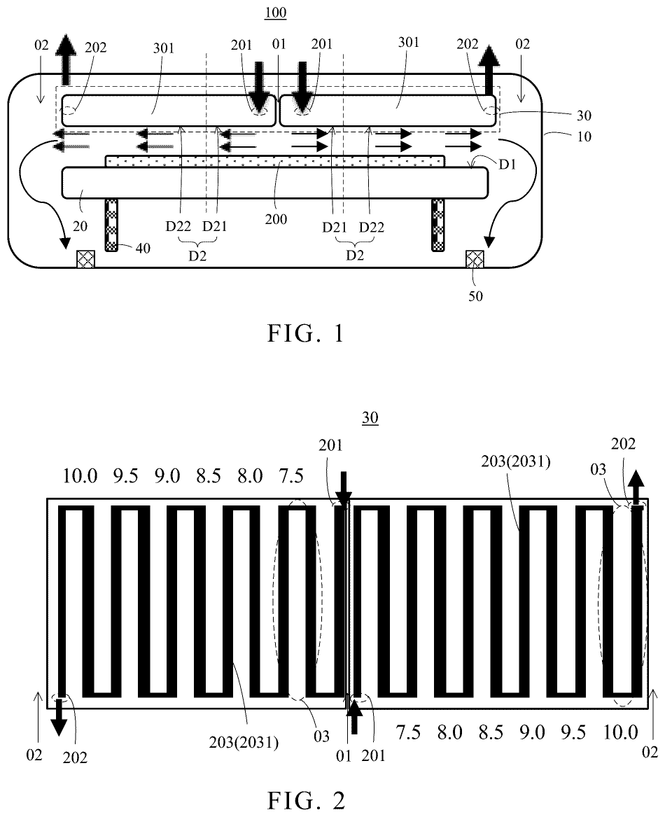

In some embodiments, referring to FIG. 1 and FIG. 2, FIG. 2 is a schematic top view diagram of the condenser 30 in FIG. 1. The condenser 30 includes at least one inlet 201 configured to allow a medium to flow into the condenser 30 and at least one outlet 202 configured to allow the medium to flow out of the condenser 30; and a temperature of the medium when the medium flows out of the condenser 30 is higher than a temperature of the medium when the medium flows into the condenser 30. Specifically, the medium may flow into the condenser 30 from the inlet 201 and flow out of the condenser 30 from the outlet 202. It should be noted that, in the prior art, the medium in the condenser is generally controlled to have a higher flow rate, so that the temperature of the medium remains basically unchanged throughout the entire process of flowing through the condenser. That is, the temperature of the medium when flowing out of the condenser is equal to the temperature of the medium when flowing into the condenser in the prior art, thus causing the problem of uneven display of the image mentioned above.

It can be understood that, in the embodiments of the present disclosure, the temperature of the medium when flowing out of the condenser 30 is higher than the temperature of the medium when flowing into the condenser 30, meaning that the temperature of the medium changes throughout the entire process of flowing through the condenser 30. For example, the medium in the condenser 30 can be controlled to have a lower flow rate, so as to achieve the above temperature changes. In some embodiments, by setting quantities and positions of inlets 201 and outlets 202, as well as the flow rate of the medium in the condenser 30 in a reasonable manner, it can be achieved that the temperature of the first part D21 of the second side D2 is lower than the temperature of the second part D22 of the second side D2, thereby reducing the risk of uneven display in the OLED display panel formed in the later stage.

In some embodiments, as shown in FIG. 1 and FIG. 2, the condenser 30 further includes a pipeline 203 configured to allow the medium to circulate, and the temperature of the medium when flowing close to the outlet 202 is higher than the temperature of the medium when flowing close to the inlet 201. Specifically, according to the above description, the temperature of the medium when flowing out of the condenser 30 is higher than the temperature of the medium when flowing into the condenser 30, which means that the temperature of the medium when entering the condenser 30 is lower, and as time increases, the medium absorbs external heat, causing an increase in temperature. Further, since the medium flows along the pipeline 203, it can be understood that the temperature is higher when it is closer to the outlet 202 and lower when it is closer to the inlet 201.

In some embodiments, as shown in FIG. 1 and FIG. 2, the condenser 30 includes at least two sub-condensers 301, a first gap 01 is provided between two sub-condensers 301, and a second gap 02 is provided between the sub-condensers 301 and a sidewall of the cavity 10; and the inlet 201 is disposed close to the first gap 01, and the outlet 202 is disposed close to the second gap 02. According to the above description, by setting the quantities and positions of the inlets 201 and the outlets 202, as well as the flow rate of the medium in the condenser 30 in a reasonable manner, it can be achieved that the temperature of the first part D21 of the second side D2 is lower than the temperature of the second part D22 of the second side D2. Further, in the embodiments as illustrated in FIG. 1 and FIG. 2, the condenser 30 is set to include at least two sub-condensers 301, so as to form the first gap 01 different from the second gap 02, and the positions of the inlet 201 and the outlet 202 can be reasonably designed to comply with the temperature of the first part D21 of the second side D2 being lower than the temperature of the second part D22 of the second side D2.

Specifically, according to the above description, when the medium enters the condenser 30 at a lower temperature, it will absorb external heat over time, resulting in an increase in temperature. Based on the above, in the embodiments as illustrated in FIG. 1 and FIG. 2, the inlet 201 is disposed close to the first gap 01, and the outlet 202 is disposed close to the second gap 02. It can be understood that, during the process of the medium flowing in the condenser 30, a temperature of a part of the condenser 30 close to the first gap 01 is lower, and a temperature of a part of the condenser 30 close to the second gap 02 is relatively higher. Since the first gap 01 is the gap between two sub-condensers 301, and closer to the first part D21 (in the center area of the substrate 200) compared to the second gap 02, it can be achieved that the temperature of the first part D21 is lower than the temperature of the second part D22, thereby reducing the difference between the evaporation rate of the solvents from the ink close to the edge area of the substrate 200 and the evaporation rate of the solvents from the ink close to the center area of the substrate 200, and further reducing the risk of uneven display in the OLED display panel formed in the later stage

In some embodiments, as shown in FIG. 1 and FIG. 2, the sub-condenser 301 includes a sub-pipeline 2031 configured to allow the medium to circulate. The sub-pipeline 2031 is formed between the inlet 201 and the outlet 202 corresponding to the inlet 201. Specifically, the condenser 30 including two sub-condensers 301 is described as an example, as illustrated in FIG. 1 and FIG. 2. According to the above description, for each sub-pipeline 2031, the medium flows into the sub-pipeline 2031 from the inlet 201 and flows out of the sub-pipeline 2031 from the outlet 202. According to the relative position of the first gap 01 and the second gap 02, the medium flows from the center area close to the substrate 200 to the edge area close to the substrate 200, as shown in the direction of the black arrow in FIG. 1, so that the temperature of the first part D21 is lower than the temperature of the second part D22, thereby reducing the difference of the evaporation rate of the solvents from the ink between the edge area of the substrate 200 and the center area of the substrate 200, and reducing the risk of uneven display in the OLED display panel formed in the later stage.

In some embodiments, for the condenser 30 including multiple sub-condensers 301, the multiple sub-condensers 301 may be arranged in a central symmetric pattern, so that a center of the symmetric pattern is still disposed close to the center area of substrate 200. For example, the condenser 30 includes four sub-condensers 301, the four sub-condensers 301 may be arranged in an array, and a center of the array pattern may be disposed close to the center area of the substrate 200, so as to form the first gap 01 in a crossed shape. Further, as the number of the sub-condensers 301 increases, for the sub-condensers 301 adjacent to the edge of the substrate 200, the corresponding second gap 02 remains at a side of the sub-condensers 301 away from the edge of the substrate 200.

In some embodiments, for the sub-condensers 301 that are not adjacent to the edge of the substrate 200 (not shown in the figures), the first gap 01 can be formed around each sub-condenser 301, in this case, one of multiple first gaps 01 closest to the sidewall of the cavity 10 can be defined as a third gap, the inlet 201 may be disposed close to the first gap 01, and the outlet 202 may be disposed close to the third gap. Especially, for the edge area and the center area of the substrate 200, the sub-condensers 301 are closer to the edge area, thus, the medium can still be controlled to have a lower flow rate and form a temperature change in the direction from the inlet 201 to the outlet 202. Otherwise, the medium can still be controlled to have a higher flow rate and almost have no temperature change in the direction from the inlet 201 to the outlet 202.

In some embodiments, as shown in FIG. 1 and FIG. 2, the sub-pipeline 2031 is circuitously arranged in a direction from the first gap 01 to the second gap 02 corresponding to the first gap 01. For example, for any of the sub-condensers 301, the sub-pipeline 2031 may sequentially extend upwards and downwards, and then downwards and upwards from the inlet 201, so as to form the circuitous arrangement. In other words, the sub-pipeline 2031 includes multiple bending parts 03 connected to each other in the horizontal direction.

It can be understood that, due to the circuitous arrangement of the sub-pipeline 2031 in the horizontal direction, in the embodiments of the present disclosure, as illustrated in FIG. 1 and FIG. 2, the temperature changes in the direction from the first gap 01 to the second gap 02 can be achieved, so as to achieve a temperature increase in the direction from the center area of the substrate 200 to the edge area of the substrate 200. Further, by setting the flow rate of the medium, the size of the multiple bending parts 03, and the distance between adjacent bending parts 03 in a reasonable manner, a sequential increase of the temperatures of the medium can be achieved when sequentially flowing into the multiple bending parts 03, so as to form a temperature gradient. For example, as shown in FIG. 2, when the medium in the sub-pipeline 2031 flows into multiple bending parts 03 sequentially in the direction from the first gap 01 to the second gap 02, the temperatures of the medium in corresponding bending parts 03 may be 7.5° C., 8.0° C., 8.5° C., 9.0° C., 9.5° C., and 10° C. sequentially.

In some embodiments, the specific temperature change in the direction from the center area of the substrate 200 to the edge area of the substrate 200 can also be reasonably set, according to the position of the extraction pump 50 located at the edge of the abutment 20 and the degree of the display difference between the sub-pixels in the edge area and the sub-pixels in the center area.

In some embodiments, as shown in FIG. 1 and FIG. 2, the extraction pump 50 is disposed close to the first gap 01 and/or the second gap 02. It can be understood that, in the above-mentioned embodiments, by setting the temperature of the first part D21 being lower than the temperature of the second part D22, the problem caused by the setting of the extraction pump 50 close to the second gap 02 in the prior art can be improved. Further, in some embodiments, the position of the extraction pump 50 can be reasonably set according to the difference between the temperature of the first part D21 and the temperature of the second part D22, so as to reduce the difference between the evaporation rate of the solvents from the ink close to the edge area of the substrate 200 and the evaporation rate of the solvents from the ink close to the center area of the substrate 200, thereby reducing the risk of uneven display in the OLED display panel formed in the later stage.

In some embodiments, when the difference between the temperature of the first part D21 and the temperature of the second part D22 is larger, that is, the difference between the temperature of the first part D21 and the temperature of the abutment 20 is large, the extraction pump 50 may be disposed close to the second gap 02, or, an extraction speed of the extraction pump 50 disposed close to the second gap 02 may be set to be greater than an extraction speed of the extraction pump 50 disposed close to the first gap 01. In some embodiments, when the difference between the temperature of the first part D21 and the temperature of the second part D22 is smaller, that is, the difference between the temperature of the first part D21 and the temperature of the abutment 20 is small, the extraction pump 50 may be set close to the first gap 01, or, the extraction speed of the extraction pump 50 disposed close to the second gap 02 may be set to be less than the extraction speed of the extraction pump 50 disposed close to the first gap 01.

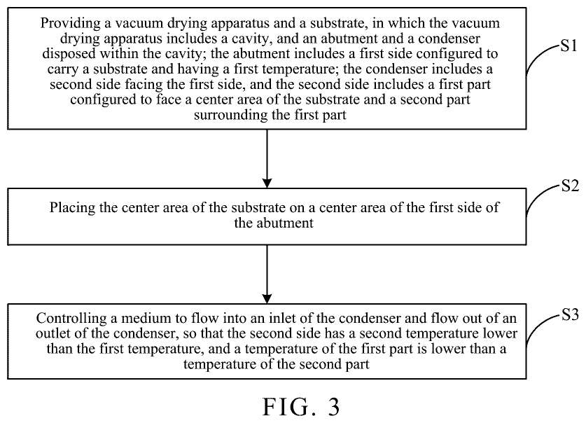

Embodiments of the present disclosure further provide a vacuum drying method using the vacuum drying apparatus 100 as described above. Referring to FIG. 1, FIG. 2, and FIG. 3, the vacuum drying method includes, but not limited to, the following steps S1, S2, and S3.

In step S1, a vacuum drying apparatus and a substrate are provided. The vacuum drying apparatus includes a cavity, and an abutment and a condenser disposed within the cavity; the abutment includes a first side configured to carry a substrate and having a first temperature; the condenser includes a second side facing the first side, and the second side includes a first part configured to face a center area of the substrate and a second part surrounding the first part. In some embodiments, the condenser in the vacuum drying apparatus includes a second side facing the first side and multiple sub-condensers.

Referring to FIG. 1 and FIG. 2, the first side D1 of the abutment 20 may have the first temperature by heating the abutment 20. It is clear that the abutment 20 may also serve as a heating source.

In step S2, the center area of the substrate is placed on a center area of the first side of the abutment.

Specifically, referring to FIG. 1 and FIG. 2, the chamber door may be opened, and then the substrate 200 is placed on the first side D1 of the abutment 20 by the lifting column 40. The first side D1 can be controlled to have the first temperature before or after the substrate 200 being placed on the first side D1 of the abutment 20.

In step S3, a medium is controlled to flow into the inlet of each sub-condenser and flow out of the outlet of each sub-condenser corresponding to the inlet, so that the second side has a second temperature lower than the first temperature, and a temperature of a first part of the second side facing the center area of the substrate is lower than a temperature of a second part surrounding the first part.

Specifically, referring to FIG. 1 and FIG. 2, the medium can be controlled to simultaneously flows into the inlet 201 and flows out of the outlet 202 of each sub-condenser 301 corresponding to the inlet 201. According to the relevant description mentioned above, during the process of the medium flowing from the inlet 201 to the outlet 202, the temperature of the medium will gradually decrease, so as to meet the requirement that the temperature of the first part D21 of the second side D2 facing the center area of the substrate 200 is lower than the temperature of the second part D22 surrounding the first part D21, thereby reducing the difference of the evaporation rate of solvents from the ink between the edge area of the substrate 200 and the center area of the substrate 200, and further reducing the risk of uneven display in the OLED display panel formed in the later stage.

Embodiments of the present disclosure further provide a display panel prepared using the vacuum drying apparatus as described in any of the above-mentioned embodiments.

The present disclosure provides the vacuum drying apparatus, the vacuum drying method, and the display panel in which the substrate is dried by the vacuum drying apparatus. The vacuum drying apparatus includes the cavity, and the abutment and the condenser disposed within the cavity. The abutment includes the first side configured to carry the substrate and having the first temperature; the condenser includes the second side facing the first side and having the second temperature lower than the first temperature. The second side includes the first part configured to face the center area of the substrate and the second part surrounding the first part, and the temperature of the first part is lower than the temperature of the second part. Based on the above configuration, the present disclosure can compensate for the faster evaporation rate of the solvents from the ink close to the edge of the substrate caused by the extraction pump, and reduce the difference between the evaporation rate of the solvents from the ink close to the edge area of the substrate and the evaporation rate of the solvents from the ink close to the center area of the substrate, thereby reducing the risk of uneven display in the OLED display panel formed in the later stage.

The disclosure provides a detailed description to the vacuum drying apparatus, the vacuum drying method, and the display panel provided by the embodiments of the present disclosure. In this context, specific embodiments are applied to explain the principles and implementation methods of the present disclosure. The description of the above embodiments is only used to help understand the technical solutions and the core idea of the present disclosure. Ordinary skilled in the art should understand that they can still modify the technical solutions recorded in the aforementioned embodiments, or equivalently replace some of the technical features. These modifications or substitutions do not separate the essence of the corresponding technical solutions from the scope of the technical solutions of the various embodiments of the present disclosure.

What is claimed is:

1. A vacuum drying apparatus comprising:
a cavity;
an abutment disposed within the cavity and comprising a first side configured to carry a substrate and having a first temperature; and
a condenser disposed within the cavity and comprising a second side facing the first side and having a second temperature lower than the first temperature;
wherein the second side comprises a first part configured to face a center area of the substrate and a second part surrounding the first part, wherein a temperature of the first part is lower than a temperature of the second part.

2. The vacuum drying apparatus of claim 1, wherein the condenser further comprises:
at least one inlet configured to allow a medium to flow into the condenser in the center area; and
at least one outlet configured to allow the medium to flow out of the condenser;
wherein a temperature of the medium when the medium flows out of the condenser is higher than a temperature of the medium when the medium flows into the condenser.

3. The vacuum drying apparatus of claim 2, wherein the condenser further comprises a pipeline configured to allow the medium to circulate;
wherein a temperature of the medium when the medium flows close to the at least one outlet is higher than a temperature of the medium when the medium flows close to the at least one inlet.

4. The vacuum drying apparatus of claim 2, wherein the condenser further comprises at least two sub-condensers, wherein a first gap is provided between two sub-condensers among the at least two sub-condensers in the center area, and a second gap is provided between the at least two sub-condensers and a sidewall of the cavity;
wherein the at least one inlet is disposed close to the first gap, and the at least one outlet is disposed close to the second gap.

5. The vacuum drying apparatus of claim 4, wherein at least one of the at least two sub-condensers comprises a sub-pipeline configured to allow the medium to circulate;
wherein the sub-pipeline is disposed between the at least one inlet and the at least one outlet corresponding to the at least one inlet.

6. The vacuum drying apparatus of claim 5, wherein the sub-pipeline is circuitously disposed in a direction from the first gap to the second gap corresponding to the sub-pipeline.

7. The vacuum drying apparatus of claim 5, wherein the sub-pipeline comprises a plurality of bending parts disposed in a direction from the first gap to the second gap, and temperatures of the medium sequentially increases along the plurality of bending parts.

8. The vacuum drying apparatus of claim 4, wherein the cavity further comprises an extraction pump disposed close to the first gap and/or the second gap.

9. The vacuum drying apparatus of claim 1, wherein the condenser further comprises an extraction pump disposed close to an edge of the abutment.

10. The vacuum drying apparatus of claim 1, wherein the substrate is an organic light-emitting diode (OLED) display panel to be dried.

11. A vacuum drying method comprising:
providing a vacuum drying apparatus and a substrate, wherein the vacuum drying apparatus comprises a cavity, and an abutment and a condenser disposed within the cavity; the abutment comprises a first side configured to carry a substrate and having a first temperature; the condenser comprises a second side facing the first side, and the second side comprises a first part configured to face a center area of the substrate and a second part surrounding the first part;
placing the center area of the substrate on a center area of the first side of the abutment; and
controlling a medium to flow into an inlet of the condenser and flow out of an outlet of the condenser, so that the second side has a second temperature lower than the first temperature, and a temperature of the first part is lower than a temperature of the second part.

12. A display panel prepared using a vacuum drying apparatus, wherein the vacuum drying apparatus comprises:
a cavity;
an abutment disposed within the cavity and comprising a first side configured to carry a substrate and having a first temperature; and
a condenser disposed within the cavity and comprising a second side facing the first side and having a second lower than temperature lower than the first temperature;
wherein the second side comprises a first part configured to face a center area of the substrate and a second part surrounding the first part, wherein a temperature of the first part is lower than a temperature of the second part.

13. The display panel of claim 12, wherein the condenser further comprises:
at least one inlet configured to allow a medium to flow into the condenser in the center area; and
at least one outlet configured to allow the medium to flow out of the condenser;
wherein a temperature of the medium when the medium flows out of the condenser is higher than a temperature of the medium when the medium flows into the condenser.

14. The display panel of claim 13, wherein the condenser further comprises a pipeline configured to allow the medium to circulate;
wherein a temperature of the medium when the medium flows close to the at least one outlet is higher than a temperature of the medium when the medium flows close to the at least one inlet.

15. The display panel of claim 13, wherein the condenser further comprises at least two sub-condensers, wherein a first gap is provided between two sub-condensers among the at least two sub-condensers in the center area, and a second gap is provided between the at least two sub-condensers and a sidewall of the cavity;
wherein the at least one inlet is disposed close to the first gap, and the at least one outlet is disposed close to the second gap.

16. The display panel of claim 15, wherein at least one of the at least two sub-condensers comprises a sub-pipeline configured to allow the medium to circulate;
wherein the sub-pipeline is disposed between the at least one inlet and the at least one outlet corresponding to the at least one inlet.

17. The display panel of claim 16, wherein the sub-pipeline is circuitously disposed in a direction from the first gap to the second gap corresponding to the sub-pipeline.

18. The display panel of claim 16, wherein the sub-pipeline comprises a plurality of bending parts disposed in a direction from the first gap to the second gap, and temperatures of the medium sequentially increases along the plurality of bending parts.

19. The display panel of claim 15, wherein the cavity further comprises an extraction pump disposed close to the first gap and/or the second gap.

20. The display panel of claim 12, wherein the condenser further comprises an extraction pump disposed close to an edge of the abutment.
